(19) United States
(12) Patent Application Publication
(10) Pub. No.: US 2026/0206167 A1
(43) Pub. Date: Jul. 16, 2026

(54) Compact High-Voltage Devices

(71) Applicant: University of Connecticut, Farmington, CT (US)

(72) Inventors: Yang Cao, Glastonbury, CT (US); Dong Dong, Blacksburg, VA (US)

(73) Assignee: University of Connecticut, Farmington, CT (US)

(21) Appl. No.: 19/446,299

(22) Filed: Jan. 12, 2026

Related U.S. Application Data
(60) Provisional application No. 63/744,337, filed on Jan. 12, 2025.

(51) Int. Cl. H05K 7/14; H05K 7/20

(52) U.S. Cl. CPC H05K 7/14324; H05K 7/14339; H05K 7/2089; H05K 7/209

(57) ABSTRACT

A modular gas-insulated gas-cooled high-voltage converter station, a method of operating, and an electric power switching module are provided. The converter station includes at least one gas-insulated enclosure having a circuit configured to convert electrical power. A fill gas is provided in fluid communication with the gas-insulated enclosure and in thermal communication with the circuit, the fill gas having a Global Warming Potential (GWP) of less than 5000.

### CROSS-REFERENCE TO RELATED APPLICATIONS

The present application is a nonprovisional application of, and claims the benefit of, U.S. Provisional Application 63/744,337 filed Jan. 12, 2025 entitled “Compact High Voltage Devices”, the contents of which are incorporated by reference herein.

### BACKGROUND

The invention disclosed herein relates to components for electrical transmission, and in particular to reduced size components high-voltage devices State-of-art high-voltage direct current (HVDC) converter stations typically rely on ambient air to insulate electric signals. The uniform breakdown strength of air under ambient conditions (1 atmospheric pressure (atm)) is only 3 kV/mm. With ever increasing voltage of HVDC transmission voltages of >500 kv, there is a growing demand for substantial separation of components.

High-voltage (HV) converter stations represent a prominent subsystem for HVDC and flexible-AC enabled smart-grids. These stations provide for dynamic power flow transmission and control, which allows for renewable energy (such as off-shore wind, solar farms) grid-integration and the alleviating of grid decongestion. Since 2003, Modular Multilevel Converter (MMC) technology has dominated the voltage-source-converter-based HVDC solutions due to its modularity, flexibility, and power quality. Unfortunately, many applications cannot take adequate advantage of the MMC technology due to present size limitations.

As shown in FIG. 1A, a substation 100 incudes a relatively large enclosure, sometimes referred to as a valve Hall 102. Electrical power is transferred into the valve Hall 102 via a feeder 104. The feeder 104 connects with a stack 106 that is comprised of an array of valves 108 or high voltage thyristor switch 112 (FIG. 1B). To avoid issues such as arcing, large hollow corona shields 110 are arranged on the top, bottom, and sides of the stack 106, with reduced or minimized surface curvature and micro-protrusions, to avoid the risks of flashover and (partial) discharges. Even with stringent control of valve hall air quality, the maximal surface field of corona shields can be designed to ~1 kV/mm, as a result the valve Hall 102 occupies a large footprint, i.e., ceiling suspensor of ~5 m and HV wall-feedthrough feeder 104 length of ~16 m.

It should be appreciated that as a result of the through-air spacing requirements, modern valve halls are quite large with a typical valve hall being 60 meters long by 25 meters wide by 18 meters high. Further, as the demand for electrical power increases, the footprint occupied by substations is increasing. Such large infrastructure limits the adoption of HVDC in space/weight sensitive applications and/or outdoor places, like offshore wind platform and underground substations.

The continuing development of diverse generation assets as well as new points of distribution and use, demands, it is desired to have additional infrastructure for transmission and distribution of electricity.

Thus, what are needed are methods and apparatus to reduce the size of components needed for transmission and distribution of high-voltage direct current (HVDC) signals such as power converter modules having the features described herein.

### SUMMARY

According to one aspect of the present disclosure, a modular gas-insulated gas-cooled high-voltage converter station is provided. The converter station includes at least one gas-insulated enclosure having a circuit configured to convert electrical power. A fill gas is provided in fluid communication with the gas-insulated enclosure and in thermal communication with the circuit, the fill gas having a Global Warming Potential (GWP) of less than 5000.

According to another aspect of the present disclosure, a method for reducing the size of a high-voltage converter station is provided. The method includes providing at least one gas-insulated gas enclosure having a PEBB disposed therein. A fill gas mixture having a GWP below 5000 is disposed in fluid communication with the PEBB. The PEBB is electrically isolated from the at least one gas-insulated enclosure based at least in part on the fill gas. Heat is transferred from the PEBB to the fill gas.

According to still another aspect of the present disclosure an electric power switching module is provided. The switching module includes a gas-insulated enclosure defining an interior space. A PEBB is disposed within the interior space, the PEBB configured to switch electrical power. A corona shield is disposed in the interior space and at least partially between the PEBB and the gas-insulated enclosure. A manifold is fluidly coupled to the interior space. A fill gas is provided in fluid communication with the interior space, the fill gas having a dielectric strength of at least 27.5 kV across a 2.5 mm gap at 1 bar and a GWP of less than 2400.

These and other advantages and features will become more apparent from the following description taken in conjunction with the drawings.

### BRIEF DESCRIPTION OF THE DRAWINGS

The subject matter, which is regarded as the disclosure, is particularly pointed out and distinctly claimed in the claims at the conclusion of the specification. The foregoing and other features, and advantages of the disclosure are apparent from the following detailed description taken in conjunction with the accompanying drawings in which:

FIG. 1A is an schematic diagram depicting aspects of components for high voltage transmission and distribution according to an embodiment;

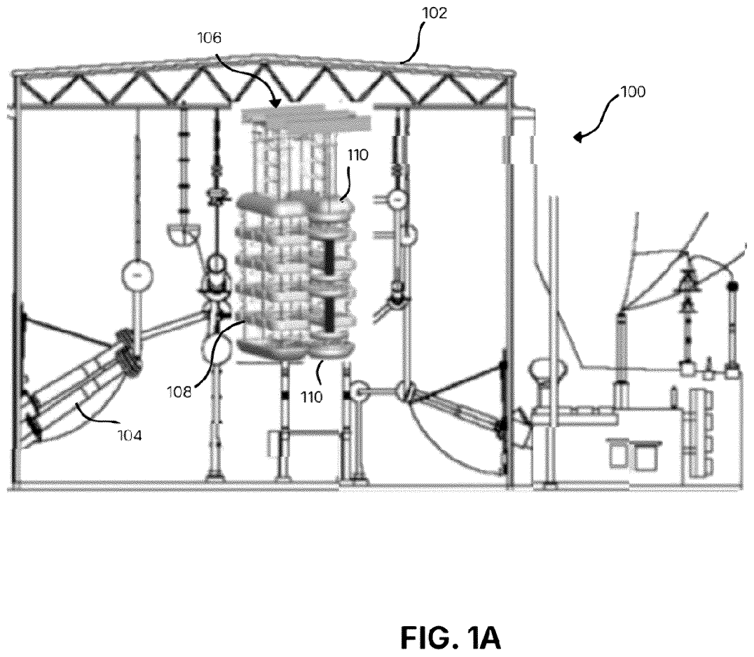

FIG. 1B is a partial perspective view of a HVDC gas insulated module according to an embodiment;

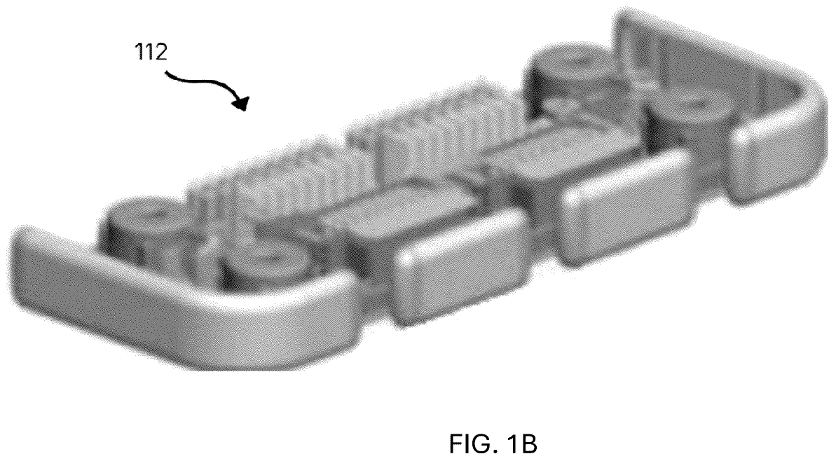

FIG. 2 is a graph depicting electrode separation for a variety of dielectric materials based on breakdown voltage;

FIG. 3A is a perspective view of a HVDC gas insulated module with a geometry enabled by implementation of C4F-N gas as the dielectric material;

FIG. 3B is a schematic illustration showing the internal arrangement of the HVDC gas-insulated module according to an embodiment; and

FIG. 3C is a perspective view of array of HVDC gas-insulated modules according to an embodiment; and

FIG. 3D is a schematic view of a power electronics building block according to an embodiment.

### DETAILED DESCRIPTION

Disclosed herein are apparatus for transmission and distribution of electrical signals such as high-voltage direct current (HVDC) signals. Generally, the apparatus provide substantially reduced component sizing for a comparative system. Prior to introducing the technology in depth, some context is provided.

High Voltage Direct Current (HVDC) power is preferred for transmitting electrical power over long distances due to its ability to reduce or minimize power losses in transmission. Unlike alternating current (AC) systems, HVDC systems avoid issues such as reactive power losses and the skin effect. HVDC technology enables electricity to be transported more efficiently across vast distances, as it allows for direct conversion of AC to DC at the source, followed by transmission at high voltages with reduced losses. This is particularly advantageous in scenarios where power must traverse oceans, rugged terrains, or connect remote renewable energy sources to the main grid. Additionally, HVDC systems offer flexibility by enabling interconnection of grids operating at different frequencies and allowing for the use of longer cables without technical restrictions, further emphasizing their suitability for long-distance power transmission. This efficiency makes HVDC ideal for transporting electricity over vast distances, particularly in scenarios where power needs to cross oceans, mountainous terrain, or connect remote renewable energy sources to the main grid.

HVDC transmission typically operates at voltage levels ranging from 100 kV to 800 kV, and in some advanced systems, it can go up to 1,100 kV. These high voltages enable large quantities of electricity to be transmitted over long distances with significantly reduced losses.

Components of HVDC transmission systems include converters (which convert AC to DC and vice versa) transformers (which step up or step down the voltage levels), smoothing reactors (which reduce ripple in the DC current), filters (to eliminate harmonics), and transmission lines (which carry the high-voltage DC power). The converter station is part of HVDC systems and consists of valves 108, usually made of thyristors or insulated-gate bipolar transistors (IGBTs), such as thyristor switch 112 for example, which control the conversion process. These components together form a robust system capable of transferring electricity efficiently across regions, making HVDC a desired choice for long-distance, high-capacity power transmission.

Advantageously, HVDC systems can transfer power between networks that operate at different frequencies, such as 50 and 60 Hz. There is no technical limit on cable length, thus HVDC systems can use longer cables or overhead lines than AC systems. As DC electricity has no frequency, so HVDC systems are less affected by corona discharge, which can reduce the need for bundling conductors together. HVDC systems can stabilize networks against disturbances caused by rapid power changes. HVDC systems require fewer conductors and cables than AC systems, which can reduce the cost of cabling.

HVDC systems work by converting AC power to DC at the sending end, transmitting the DC power, and then converting the DC power back to AC at the receiving end. The main types of HVDC transmission systems include monopolar, bipolar, homopolar, back-to-back, and multiterminal.

A converter station is a component of an HVDC (High Voltage Direct Current) transmission system, responsible for converting electrical power between alternating current (AC) and direct current (DC). These stations are located at both ends of an HVDC transmission line-one at the sending end to convert AC to DC (rectifier station) and another at the receiving end to convert DC back to AC (inverter station). Converter stations enable the integration of HVDC technology into existing AC networks and facilitate the efficient transfer of power over long distances.

Components of a converter station include converter valves (and other elements listed below). Converter valves are the heart of the converter station, where the actual conversion between AC and DC occurs. They are composed of semiconductor devices, such as thyristors or insulated-gate bipolar transistors (IGBTs), arranged in series to handle high voltages. The valves control the direction and flow of electricity, ensuring efficient conversion.

A thyristor valve, as utilized in HVDC converter stations, comprises multiple semiconductor devices known as thyristors, arranged in series to manage high-voltage operations. These thyristors are specifically designed to control the flow and direction of electricity, facilitating the conversion process between alternating current (AC) and direct current (DC). Each thyristor within the valve includes a control mechanism allowing desired regulation of power handling. The valve structure typically integrates features such as cooling systems to dissipate heat and protective components to safeguard against voltage surges and electrical faults. This arrangement ensures robust and reliable function within the HVDC system, supporting efficient transmission over extended distances.

Also included are transformers. Converter transformers step up or step down the AC voltage to the appropriate level for conversion. They provide electrical isolation between the AC system and the HVDC system, ensuring safety and efficiency. These transformers are specially designed to handle the requirements of HVDC systems, including high voltage levels and the ability to manage harmonic currents.

Smoothing reactors are large inductors placed on the DC side of the converter station. They smooth out fluctuations and ripples in the DC current, providing a more stable and consistent power flow. This helps in reducing electrical losses and protecting the system from potential damage caused by current surges.

Both AC and DC filters are installed to eliminate undesired harmonics generated during the conversion process. These harmonics can cause interference with nearby communication lines or equipment, so filters are used to maintain power quality and reduce or minimize electromagnetic interference.

Switchgear and circuit breaker components provide protection and control for the converter station, allowing sections of the system to be isolated in case of faults or maintenance requirements. They ensure the safety and reliability of the HVDC transmission system.

A cooling system is often included as the conversion process generates a significant amount of heat, especially in the converter valves. A cooling system, typically using water or oil, is employed to dissipate this heat and maintain desired operating temperatures for the equipment.

Materials with excellent dielectric properties are desired in HVDC (High Voltage Direct Current) converter stations to ensure insulation, reliability, and safety. These materials prevent electrical breakdowns, manage high-voltage stress, and protect sensitive components within the converter station. Their dielectric strength, electrical resistance, and stability under high-voltage conditions make them ideal for use in HVDC applications. Some dielectric materials used in HVDC converter stations are now introduced.

Polyethylene (PE) and Cross-Linked Polyethylene (XLPE) are widely used for insulating cables in HVDC systems due to their high dielectric strength, low dielectric loss, and excellent thermal stability. XLPE, a chemically cross-linked version of polyethylene, offers enhanced thermal and mechanical properties, making it ideal for high-voltage applications. It can handle voltage stresses of up to 500 kv, making it a preferred choice for HVDC cable insulation.

Epoxy Resins are frequently used as insulating materials in bushings, transformer windings, and valve hall components within converter stations. They provide high dielectric strength, excellent thermal conductivity, and good resistance to environmental factors such as moisture and chemical exposure. Epoxy resins can be molded into complex shapes, making them suitable for various insulation needs in HVDC converter stations.

Mineral oil may be used as a dielectric coolant in HVDC transformers, mineral oil serves a dual purpose by providing insulation and cooling. It has a high dielectric strength and is effective in dissipating heat generated within the transformers, preventing overheating and maintaining operational efficiency. Regular testing and maintenance are essential to ensure the oil retains its insulating properties over time.

Ceramics and porcelain materials are employed in insulators, bushings, and valve stacks, offering high dielectric strength, mechanical robustness, and resistance to high temperatures. Ceramics and porcelain are effective in withstanding high electrical stresses while providing structural support, making them suitable for outdoor applications and extreme environmental conditions.

Gas insulation has often used sulfur hexafluoride (SF₆) in some electrical components within HVDC converter stations, such as gas-insulated switchgear (GIS) and circuit breakers for example. It has desired dielectric properties, offering high insulation strength and arc-quenching capabilities. The ability of SF6 to handle high voltages and withstand electrical stresses makes it desired for use in confined spaces, where traditional insulation materials may not be practical. However, SF₆ is also a potent greenhouse gas with a significant impact on climate change.

As used herein, “Global Warming Potential (GWP)” is a measure used to compare the ability of different greenhouse gases to trap heat in the Earth's atmosphere relative to carbon dioxide (CO₂). It quantifies the impact of a gas on global warming over a specified time period, typically 20, 100, or 500 years. GWP is expressed as a ratio, where CO2 has a GWP of 1, and other gases are compared to this baseline.

SF₆ has an extremely high GWP of approximately 23,500 times that of carbon dioxide (CO2) over a 100-year period. This means that 1 ton of SF 6 has the same warming effect as 23,500 tons of CO2. The ability of SF₆ to trap heat in the atmosphere makes it one of the most potent greenhouse gases known.

Additionally, SF 6 has a long atmospheric lifespan, estimated to be around 3,200 years, meaning it remains in the atmosphere for millennia. Once released, it contributes to global warming for an extended period, making its environmental impact long-lasting and cumulative.

One problem with use of SF₆ in sealed systems is that leaks can occur during manufacturing, maintenance, and disposal processes. Even small leaks can be significant due to the high GWP, contributing to its overall environmental footprint. Given its impact, there is increasing concern about the use of SF₆ and efforts to mitigate its environmental effects.

According to one or more embodiments, a modular gas-insulated gas-cooled converter station is provided that allows for efficient high-voltage power conversion and transmission. Such systems may be characterized in a few ways. For example the station may be modular. In this embodiment, the station is constructed in sections or units that can be easily added, removed, or reconfigured to scale or adapt to desired needs. This enhances flexibility and simplifies maintenance and upgrades. The station may be comprised of gas-insulated components or equipment. The electrical equipment (such as transformers, circuit breakers, and busbars) is insulated using pressurized gas, typically sulfur hexafluoride (SF₆). Gas insulation is preferred because it allows equipment to be more compact, safe, and reliable compared to air-insulated designs, especially in confined spaces. The station may be gas-cooled. In addition to gas insulation, the station may use a gas medium, such as SF₆ or a mixture of gases, to cool the electrical components or equipment. This cooling provides desired operation and prevents overheating, which is desired in high-power applications. The station is further configured to convert electrical energy from alternating current (AC) to direct current (DC) or vice versa. Converter stations are are used in high-voltage direct current (HVDC) power transmission systems, which are used for efficient long-distance transmission and integration of renewable energy sources.

It should be appreciated that while embodiments herein may refer to the use of sulfer hexafluoride as a gas insulator or coolant, it should be appreciated that other gases, having lower GWP may be used, such as but not limited to Fluoronitrile/CO2 mixtures; Novec 4710 (C₄F₇N); Trifluoroiodomethane (CF3I); Octafluorocyclobutane (CAF8); Carbon Dioxide (CO2) with Additives (used in combination with other gases to enhance dielectric properties and reduce environmental impact); and Nitrogen (N2) with Fluorinated Compounds for example.

In an embodiment, C₄F₇N may have a dielectric strength of 27.5 kV across a 2.5 mm gap at 1 bar (14.5 psia). It has been found that the dielectric strength C₄F₇N may be increased by mixing with carbon dioxide. In an embodiment, the working gas or fill gas is at least 20% C₄F₇N mixed with carbon dioxide.

These stations are used in power transmission systems where high voltage and long distances are involved, often in conjunction with renewable energy projects like offshore wind farms or large-scale solar installations. They offer compact design, reliability, and efficiency, especially in environments where space is constrained, such as urban areas or offshore platforms.

Included in many modular designs are the power electronics building block (PEBB). In electric transmission, the PEBB is a standardized module that integrates power semiconductor devices, gate drives, thyristor switches, sensors, and control hardware to perform various power conversion functions. PEBBs are fundamental components in power electronics systems used for managing and converting electrical power in applications such as electric transmission, particularly in high-voltage direct current (HVDC) systems, renewable energy integration, and smart grids.

The PEBB has a number of advantages including standardization. PEBBs are designed to be modular and interchangeable, meaning they can be used in various power electronics systems with reduced or minimal customization. This provides advantages in reducing design complexity and facilitating upgrades and maintenance. Each PEBB integrates multiple functionalities such as power conversion (e.g., AC to DC, DC to AC), control circuits, and thermal management. This allows for efficient, compact, and high-performance power management systems. PEBBs can be combined to form larger systems that handle higher power levels (scalability), which is particularly useful in electric transmission, where scalability and efficiency are critical for managing large-scale energy flows. PEBBs are commonly used in converters (like those found in HVDC systems), inverters, motor drives, and energy storage systems. In electric transmission, they enable efficient, reliable, and flexible power conversion, which is vital for integrating renewable energy sources and improving grid stability. Overall, PEBBs help streamline power electronics design, reduce system costs, and improve the flexibility and efficiency of modern electric transmission systems.

Advantageously, the inventors have found that gas that contains a mixture of about 20% fluoronitrile with CO2 mixture constitutes a promising potential replacement of SF₆. The fluoronitrile/CO₂ mixture offers several advantages including: a significantly lower GWP compared to SF₆, making it a more environmentally friendly option. The mixture retains good dielectric (insulating) properties that are comparable to those of SF₆, making it suitable for use in electrical insulation applications. Additionally, the fluoronitrile/CO₂ mixture can effectively quench electrical arcs, a desired function in high-voltage electrical systems.

Additionally, other combinations of gases may be used. For example, Novec 4710® (a product of 3M Corporation) has the chemical formula C₄F₇N. This gas belongs to the fluoronitrile family, featuring both fluorine and nitrogen atoms in its structure. This gas offers excellent dielectric properties, making it highly effective for insulation in high-voltage equipment like gas-insulated switchgear (GIS) and circuit breakers. This gas is effective at extinguishing electrical arcs, which is crucial for the safe operation of high-voltage electrical systems. One of the standout features of the gas is its much lower global warming potential (GWP) compared to SF₆. While SF₆ has a GWP of around 23,500 over a 100-year period, Novec 4710 has a GWP of about 2,100, making it a less impactful choice. Additionally, the gas is thermally stable and performs well over a wide range of temperatures, making it suitable for various climate conditions. The gas is often used in combination with other gases, such as carbon dioxide (CO2) or nitrogen (N2), to create gas mixtures that can serve as alternatives to SF₆ in high-voltage applications. These mixtures maintain the necessary insulating and arc-quenching capabilities while significantly reducing the environmental impact.

The gas may be used in, for example, gas-insulated switchgear (GIS), high-voltage circuit breakers, power transformers and other components of transmission and distribution systems.

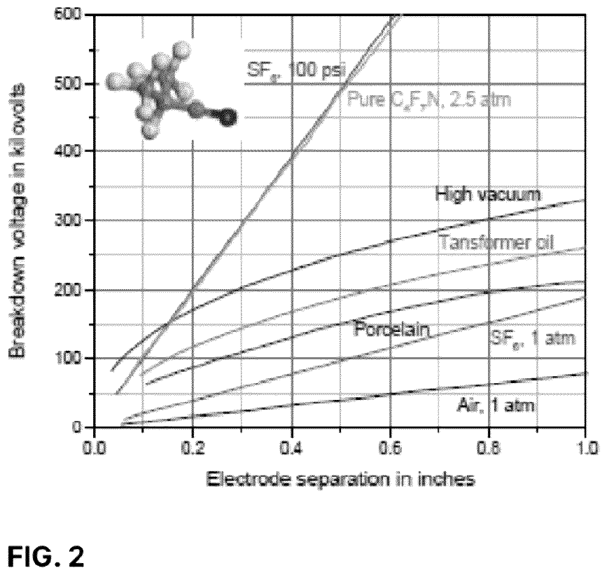

Referring now to FIG. 2, pressurized fluorinated gaseous dielectrics such as SF₆ compare favorably against the transformer oil, but as stated, use of SF₆ is limited due to the environmental concerns.

It has been found that use of the C₄F₇N (i.e., chemical name 1,1,1,4,4,4-Hexafluoro-2-butene) based insulation provides a high dielectric strength of more than two times that of SF₆, while exhibiting a low GWP of only 2400. Other tests also suggest that this gas is not Carcinogens Mutagenic Reprotoxic (CMR) and the LC50 (lethal concentration at 50% mortality) is about 12,000 ppm.

Gas insulated designs that take advantage of the teachings herein may provide for an insulation structure design with a 50 mm main gap space for a Basic Insulation Level (BIL) of 1050 kV.

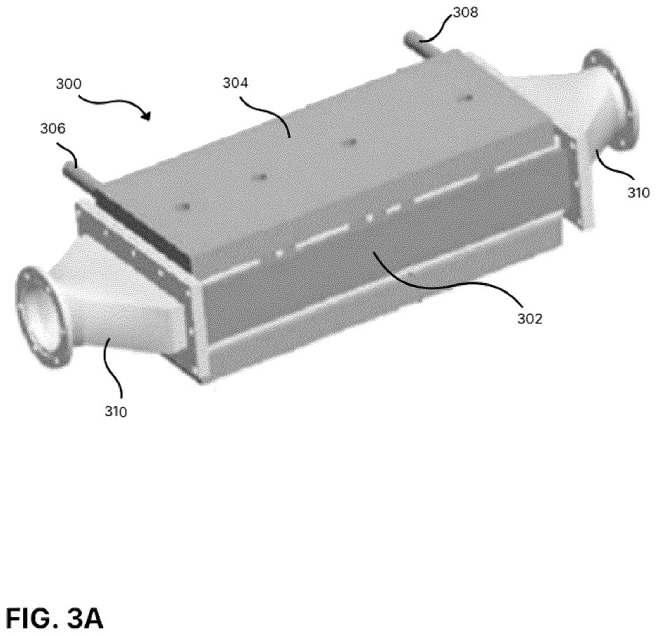

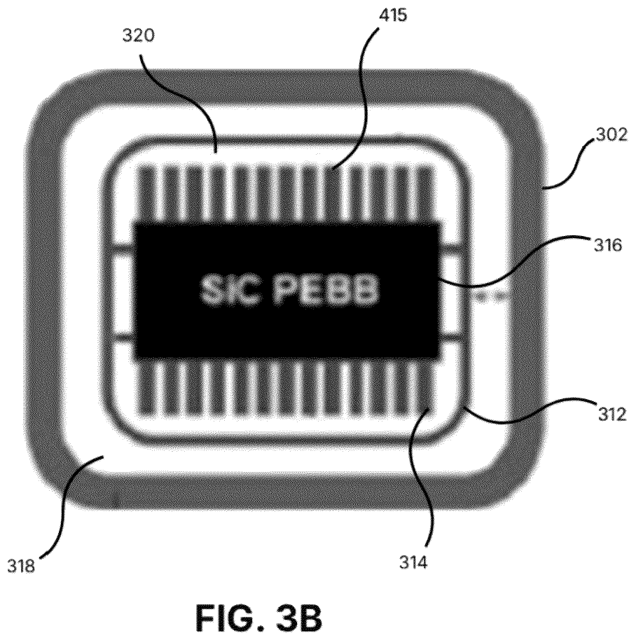

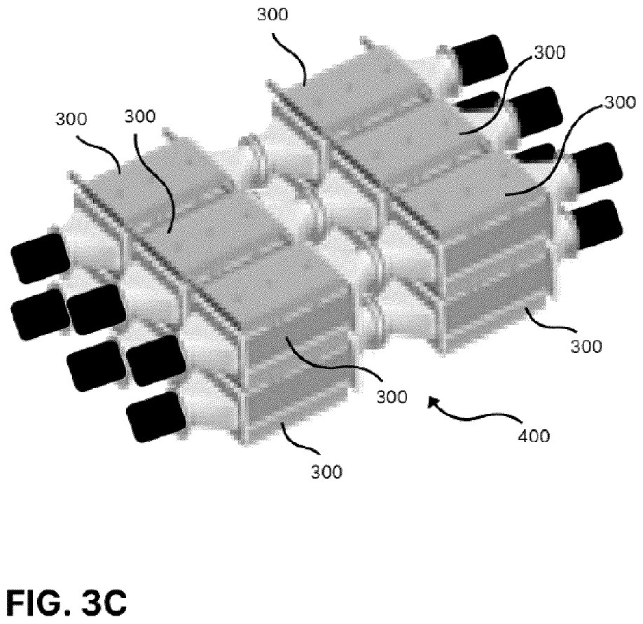

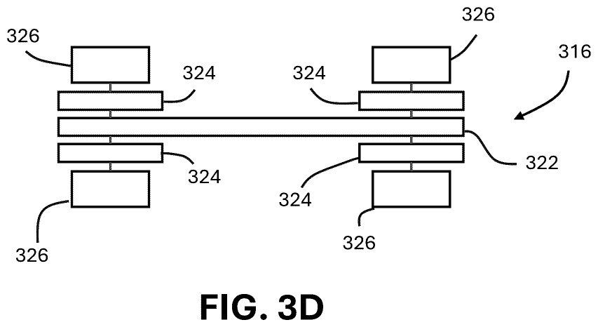

As shown in FIG. 3A and FIG. 3B, a gas insulated module 300 module is provided. The gas insulated module 300 includes gas insulated enclosure 302 that is fluidly coupled to a manifold 304. In an embodiment, the manifold 304 is configured with an gas supply inlet 306 and a outlet 308 that allows a high dielectric gas to flow into and out of the gas insulated enclosure 302. In an embodiment, the working gas is C₄F₇N which provides both electrical insulation and cooling of the internal components. In an embodiment, the manifold 304 is fluidly coupled to a heat exchanger (not show) that allow transfer of heat from the working gas to the environment or another external process. Arranged on opposite ends of the gas insulated enclosure 302 are cable connection modules 310.

The cable connection module 310 for a PEBB is designed to ensure reliable electrical connections while maintaining insulation and thermal efficiency. In one embodiment, the cable connection module 310 also provides a gas seal to prevent the flow of gas out of the gas insulated enclosure 302. In another embodiment, the 410 provide a fluid coupling to an adjacent gas insulated enclosure 302. The connector comprises a housing constructed from materials exhibiting robust dielectric properties to prevent electrical breakdown and support high-voltage operations.

It should be appreciated that while embodiments herein describe the gas insulated module 300 with respect to a PEBB, this is for example purposes and the claims should not be so limited. In other embodiments, the gas insulated module 300 may incorporate circuits having a valve 108, thyristor switches, insulated gate bipolar transistors (IGBT), snubbers, or valve reactors for example.

In an embodiment, the cable connection module 310 includes a set of terminal contacts, configured to provide secure connections with external high-voltage cables. The terminal contacts may be fabricated from conductive metals such as copper or aluminum, allowing for desired conductivity and reduced resistive losses. These contacts are arranged to ensure a low-resistance path for electrical currents, facilitating efficient power transfer.

In an embodiment, the connection module further comprises a locking mechanism to secure the connection and prevent accidental disconnections. This mechanism includes a mechanical latch or screw system that maintains structural integrity under mechanical vibrations and thermal expansions common in high-power environments.

In an embodiment, the connection modules includes an integrated gas inlet to provide a cooling interface that supports forced convective cooling of the PEBB. A gas inlet and outlet are configured to circulate a cooling medium, such as Novec 4710® (C₄F₇N), within the connector housing, to dissipate heat generated by the silicon carbide (SIC) MOSFETs and maintaining operational stability.

The gas insulated enclosure 302 defines an interior space 318 that is configured to receive and circulate the working fluid/gas for isolating and cooling the PEBB 316. An internal corona shield 312 is disposed between the gas insulated enclosure 302 and the PEBB 316. The high voltage corona shield 312 may be adapted to smooth the E-field inside the gas insulated enclosure 302. The corona shield 312 is configured to manage electric fields within high-voltage systems. The corona shield serves to prevent corona discharge, which may occur when the electric field exceeds the dielectric strength of surrounding air, thus mitigating the risk of electrical breakdown.

The corona shield 312 further provides a uniform electric field distribution, thereby reducing localized field concentrations. This functionality ensures that the voltage stress is evenly distributed within the interior space 318, reducing or minimizing the potential for insulation failure and enhancing the overall reliability of the system.

In an embodiment, the PEBB 316 includes a first set of fins 314 on a first side of the PEBB and a second set of fins 415 on a second side of the PEBB. In the illustrated embodiment, the first side and the second side are opposite each other. The fins 314 and fins 415 are in thermal communication with the heat generating components of the PEBB 316. The fins 314 and fins 415 are further in fluid communication the interior space 318. As a result, the fins 314, 415 are in thermal communication with the working fluid used to isolate and cool the PEBB 316. In the illustrated embodiment, the interior space 320 within the corona shield 312 is in fluid communication with the interior space 318. In an embodiment, heat is transferred from the fins 314, 415 to the working fluid via convection. In an embodiment, the convection is natural convection. In another embodiment a fluid movement device (e.g. a fan) is provided to allow for forced convection to be used and improve the rate of heat transfer. In still another embodiment, the fluid movement device may be selectively operated based on the operating conditions of the PEBB 316.

It should be with It should be appreciate that the use of the gas insulated enclosure 302 and the working fluid provides for improvements over the prior art valve and PEBB configurations that only had a heat sink and fins on a single side. Thus the heat transfer characteristics are improved with the present embodiments.

In an embodiment, the working fluid to isolate and cool the PEBB 316 is C₄F₇N pressurized to 2.5 atm. In this embodiment, by adopting a modular gas-insulated valve design, all the infrastructure used for air-spacing and creepage of the prior art converter station can be reduced, with a theoretical size reduction of 5 meters×5 meters×2 meters, resulting in a size reduction of up to 50 times over the prior art converter station while continuing to use existing Si thyristor switching devices.

Further, by using medium voltage SIC MOSFET device technologies, e.g. 10 to 15 kV SIC MOSFET, the MMC valve can be constructed with much fewer number of SiC-based MV PEBBs in series, leading to further reductions of dimension and high voltage connection accessories. Furthermore, the SiC MOSFETs offer >175 degrees Celsius operation junction temperature and a resistive-type on-state characteristic. The heat-flux density created by current conduction can be reduced by paralleling device chips in the modules.

Referring to FIG. 3C, an embodiment is shown of an array of gas-insulated modules 400. In this embodiment, the array of gas-insulated modules 400 is comprised of a plurality of individual gas insulated module 300 that are coupled directly adjacent to each other. In an embodiment, there is no air gap or through-air spacing between adjacent gas insulated modules 300. In an embodiment, the gas insulated module 300 can be joined together using bolted flanges through an O-ring seal, with conductors connected through the sliding plug-in contact.

It should be appreciated that this arrangement allows for further reduction in size of the converter station.

Referring now to FIG. 3D, an embodiment is shown of a PEBB 316. In this embodiment, the PEBB 316 includes an PCB, busbar and driver 322 that supports a plurality of switch modules 324. Thermally and structurally coupled to each of the switch modules 324 is a pin-fin heat sink 326.

The pin-fin heat sink is a component designed to dissipate heat efficiently within a power electronics module. It comprises an array of cylindrical pins, which are typically fabricated from thermally conductive materials such as aluminum or copper. These pins are arranged in a densely packed configuration to increase the surface area available for heat exchange. Each pin is vertically oriented and extends from a base plate, which serves as the main thermal interface to transfer heat from the heat-generating component to the pin structure. The design promotes convective heat transfer by allowing cooling fluid to flow around and between the pins, increasing or maximizing the dissipation of heat and maintaining desired operating temperatures for the electronic components. The pin-fin heat sink is integral to maintaining the thermal stability and efficiency of high-performance systems. The pin-fin heat sink 326 is configured to receive heat from the switch module 324 and transfer the heat to the working gas as described herein.

Embodiments described herein may use either natural or forced convection. It is recognized that a forced convective cooling design using a working fluid such as C₄F₇N gas to carry off the heat generated by the SiC switches for the convective cooling of a simplified straight circular pipe, the Dittus-Bolter correlation can be applied to estimate the heat transfer coefficient a between the bulk of the fluid and the pipe surface. Considering the similarities in performance between C₄F₇N and SF₆, the estimated heat transfer coefficient (a) can reach of 100 W/m\hat{ }2K, which could be further enhanced with surface turbulent flow.

The conventional challenge to adopt gas-insulation for a HVDC converter station is the large and complex enclosure for the entire valve. However, the modular-based MMC solution allows to identify the desired economic gas-insulated design from valve to module level thereby remarkably simplifying the design and enable high flexibility for system-level integration. Each gas-insulated Si or SIC Valve may employ a gas supply loop to control and circulate the pressurized gas, terminated with sealing type insulators/cable-receptacles for ease of isolation. As such, the construction of the a high-voltage converter station maybe formed by stacking modular blocks, which significantly streamlines the construction process.

Accordingly, disclosed herein is integration of the HVDC cable connection module as part of gas-insulated SiC valve for interconnection purpose. In this way, dimensional aspects of the converter station can be reduced, with an estimated (theoretical) size reduction of 5 meters×5 meters×2 meters, a total of 50 times, by adopting a modular gas-insulated valve design. Furthermore, it can be fully sealed from air, thereby eliminating bulky bushing components inside the converter station. More importantly, the large valve hall is not needed, making the technology suitable for outdoor, underground and even subsea environment. The technology disclosed herein may be integrated with gas-insulated-transmission line (GIL) and gas-insulated-switchgear (GIS) to enable a very high-density HVDC converter station, protection, and transmission system.

Generally, use of the C₄F₇N (i.e., chemical name 1,1,1,4,4,4-Hexafluoro-2-butene) is described herein provides for a dual benefit of electrical insulation and cooling of electrical apparatus. When implemented in components as described herein, the gas is referred to as a “working gas” or “fill gas.” That is, the gas is used to fill void spaces within the respective component. In order to perform the desired functions.

Generally, size reduction enabled by the use of the fill gas is with comparison to a system filled with ambient air.

Some additional features and embodiments are now introduced.

Development of HVDC conversion technologies taking advantage of the teachings herein would lead to smaller modular HVDC substations that would make long distance DC transmission and distribution more feasible. Additional increases in efficiency, power density, and reliability would be transformational to several energy related fields. The technology is particularly advantageous for utilizing advanced HVDC converters that are associated with wind farms and solar energy production.

The dual approach of using as alternative cooling gas combined with the high density SiC power electronic building blocks is very attractive. The specific goal of producing a 20 kV 100 A SIC sub-valve prototype with 99.6% efficiency and greater than 2 MW/m3 density at 1 MV insulation level offers a desired technological advancement. The interface for connecting a HVDC cable makes the proposal even stronger.

Other potential problems is gas cooling of the power modules. These risks can be mitigated by modeling dynamics with fundamental studies of the partial discharge. Use of new dielectric materials, electric field shields, and encapsulation of key components present further opportunities.

As used herein, “Global Warming Potential (GWP)” is a measure used to compare the ability of different greenhouse gases to trap heat in the Earth's atmosphere relative to carbon dioxide (CO₂). It quantifies the impact of a gas on global warming over a specified time period, typically 20, 100, or 500 years. GWP is expressed as a ratio, where CO₂ has a GWP of 1, and other gases are compared to this baseline.

The reference gas for GWP is carbon dioxide (CO₂): Carbon dioxide is used as the reference gas because it is the most prevalent and well-studied greenhouse gas. All other gases are compared to CO₂ in terms of their potential to contribute to warming. GWP is based on a time horizon, often calculated over 100 years, but shorter (20-year) or longer (500-year) time frames can also be used. The time horizon affects how the impact of a gas is viewed, as some gases break down faster than others but have a stronger short-term effect. Gases with High GWP: Methane (CH₄): Has a GWP of approximately 28-36 over 100 years, meaning methane traps significantly more heat than CO₂ but persists in the atmosphere for a shorter time. Nitrous Oxide (N₂O): Has a GWP of about 298 over 100 years. Hydrofluorocarbons (HFCs): Used in refrigeration and air conditioning, with GWPs ranging from 1,000 to 12,000 or more. Sulfur Hexafluoride (SF₆): A gas used in electrical systems, has an extremely high GWP of around 23,500. Impact on Climate Change: GWP allows policymakers and scientists to compare the relative contributions of various gases to climate change. Gases with high GWP trap more heat per unit and thus have a larger effect on global warming, even in smaller quantities. Relevance to Regulation: GWP is a key metric in climate change policies, such as the Kyoto Protocol and the Paris Agreement, which aim to reduce the emission of high-GWP gases. It is used to prioritize which gases should be controlled or phased out in efforts to mitigate climate change.

Generally, as disclosed herein, the fill gas used in devices herein may have a GWP that is below 5000, 4000, 3000, 2500, or lower. Generally, as disclosed herein, device size reduction may be a factor of 2 times, 10 times, 20 times, 30 times, 40 times, and up to as high as 50 times.

All statements herein reciting principles, aspects, and embodiments of the disclosure, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It should also be noted that the terms “first”, “second”, “third”, “upper”, “lower”, and the like may be used herein to modify various elements. These modifiers do not imply a spatial, sequential, or hierarchical order to the modified elements unless specifically stated.

Various embodiments of the invention are described herein with reference to the related drawings. Alternative embodiments of the invention can be devised without departing from the scope of this invention. Various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or an indirect coupling, and a positional relationship between entities can be a direct or indirect positional relationship. Moreover, the various tasks and process steps described herein can be incorporated into a more comprehensive procedure or process having additional steps or functionality not described in detail herein.

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” may be understood to include any integer number greater than or equal to one, i.e. one, two, three, four, etc. The terms “a plurality” may be understood to include any integer number greater than or equal to two, i.e. two, three, four, five, etc. The term “connection” may include both an indirect “connection” and a direct “connection.” The terms “about,” “substantially,” “approximately,” and variations thereof, are intended to include the degree of error associated with measurement of the particular quantity based upon the equipment available at the time of filing the application. For example, “about” can include a range of +8% or 5%, or 2% of a given value.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments described herein.

While the disclosure is provided in detail in connection with only a limited number of embodiments, it should be readily understood that the disclosure is not limited to such disclosed embodiments. Rather, the disclosure can be modified to incorporate any number of variations, alterations, substitutions or equivalent arrangements not heretofore described, but which are commensurate with the spirit and scope of the disclosure. Additionally, while various embodiments of the disclosure have been described, it is to be understood that the exemplary embodiment(s) may include only some of the described exemplary aspects. Accordingly, the disclosure is not to be seen as limited by the foregoing description, but is only limited by the scope of the appended claims.

1. A modular gas-insulated gas-cooled high-voltage converter station comprising:
at least one gas-insulated enclosure having a circuit configured to convert electrical power; and
a fill gas in fluid communication with the gas-insulated enclosure and in thermal communication with the circuit, the fill gas having a Global Warming Potential (GWP) of less than 5000.

2. The modular gas-insulated gas-cooled high-voltage converter station of claim 1, wherein the fill gas exhibits a Global Warming Potential of below 2400.

3. The modular gas-insulated gas-cooled high-voltage converter station of claim 2, wherein the fill gas is approximately 20% fluoronitrile with carbon dioxide.

4. The modular gas-insulated gas-cooled high-voltage converter station of claim 3, wherein the fill gas is C₄F₇N.

5. The modular gas-insulated gas-cooled high-voltage converter station of claim 1, wherein the the circuit is a power electronics building block (PEBB) having SIC MOSFET devices operating above 175 degrees Celsius.

6. The modular gas-insulated gas-cooled high-voltage converter station of claim 1, wherein the PEBB includes a first set of fins disposed on a first side, the first set of fins being in thermal communication with heat generating components within the PEBB and the fill gas.

7. A modular gas-insulated gas-cooled high-voltage converter station of claim 6, wherein the PEBB includes a second set of fins disposed on a second side, the second set of fins being in thermal communication with the heat generating components and the fill gas.

8. The modular gas-insulated gas-cooled high-voltage converter station of claim 7, wherein the first side is opposite the second side.

9. The modular gas-insulated gas-cooled high-voltage converter station of claim 1, further comprising a corona shield disposed between the PEBB and an inside wall of the at least one gas enclosure.

10. A method for reducing a size of a high-voltage converter station comprising:
providing at least one gas-insulated gas enclosure having a PEBB disposed therein;
disposing a fill gas mixture having a GWP below 5000 in fluid communication with the PEBB;
electrically isolating the PEBB from the at least one gas-insulated enclosure based at least in part on the fill gas; and
transferring heat from the PEBB to the fill gas.

11. The method of claim 10, wherein the fill gas exhibits a GWP equal to or less than 2400.

12. The method of claim 11 wherein the fill gas comprises about 20% fluoronitrile with carbon dioxide.

13. The method of claim 12, wherein the fill gas is C₄F₇N.

14. The method of claim 10, further including implementing SIC MOSFET devices within the PEBB to achieve compact design.

15. The method of claim 10, wherein the PEBB includes a first plurality of fins disposed on a first side and a second plurality of fins disposed on a second side.

16. The method of claim 15, further comprising transferring heat from heat generating components within the PEBB to the fill gas via the first plurality of fins and second plurality of fins.

17. The method of claim 10, further comprising disposing a corona shield between the PEBB and an inside wall of the enclosure.

18. The method of claim 10, wherein the converter station is configured to receive high-voltage direct current transmission for offshore wind platforms.

19. An electric power switching module comprising:
a gas-insulated enclosure defining an interior space;
a PEBB disposed within the interior space, the PEBB configured to switch electrical power;
a corona shield disposed in the interior space and at least partially between the PEBB and the gas-insulated enclosure;
a manifold fluidly coupled to the interior space; and
a fill gas in fluid communication with the interior space, the fill gas having a dielectric strength of at least 27.5 kV across a 2.5 mm gap at 1 bar and a GWP of less than 2400.

20. The electric power switching module of claim 19, wherein the PEBB includes a first set of fins disposed on first side and a second set of fins disposed on a second side, the first side opposite the second side, the first set of fins and second set of fins being in thermal communication between heat generating components within the PEBB and the fill gas.
